(19) United States
(12) Patent Application Publication
(10) Pub. No.: US 2025/0164527 A1
(43) Pub. Date: May 22, 2025

(54) A Probe Card Stroke Compensation System and Method

(71) Applicant: Shanghai Zenfocus Semi-Tech Co., Ltd., Shanghai (CN)

(72) Inventors: Jian Liang, Shanghai (CN); Xiongke Luo, Shanghai (CN)

(21) Appl. No.: 18/290,141

(22) PCT Filed: Aug. 19, 2022
(86) PCT No.: PCT/CN2022/113454

§ 371 Date: Feb. 6, 2025

(30) Foreign Application Priority Data
Jun. 17, 2022 (CN) 202210690404.2

(51) Int. Cl. G01R 1/067; G01R 1/073; G01R 31/28

(52) U.S. Cl. CPC G01R 1/06794; G01R 1/07342; G01R 31/2831

(57) ABSTRACT

The invention provides a probe card stroke compensation system, which can be applied to a wafer testing system, and that probe card in the wafer testing system includes a probe head, comprising a measuring unit, which is used for measuring the stroke of a single probe and the flatness of all probes, and allows to calculate the total elastic force of the probe card according to the numerical values of the stroke and flatness; a pressure sensor unit, wherein that pressure sensor and the probe head can be replaced each other, and the stroke compensation value of the probe card is obtained according to the relationship between the pressure and the stroke measured by the pressure sensor. The invention also provides a probe card stroke compensation method correspondingly.

### TECHNICAL FIELD

The invention belongs to the technical field of semiconductor testing, in particular to a probe card stroke compensation system and method.

### BACKGROUND ART

In the testing stage of semiconductor wafer, it is necessary to test the unpacked chips on the wafer. During the testing process, probe cards are used, which complete the electrical connection of the wafer pads or bumps to the test machine, and then the performance measurement of the wafer chips is completed by the test machine, and the wafers are screened and classified, and the chips that do not meet the design requirements are eliminated. The probe used in the probe card is usually only a few tens of microns in size and only 4-7 mm in length, and the elastic force of the probe is basically about 5 g (the elastic force of the probe will be different in different applications).

With the improvement of wafer manufacturing capacity and high-density market demand, the number of probes in some applications has exceeded 20000 pin, so the thrust requirement of wafer carrier in the probe station in chip testing needs to reach 100 kg, which raises the structural strength and precision requirements of probe cards and probes to a new level. After the probe is stuck on the wafer pad, it is necessary to continue to apply pressure to make the probe deform and generate greater elastic force, thus ensuring the electrical contact between the probe and the pad and ensuring the normal transmission of electrical signals between the test machine and the wafer. In the wafer test in the prior art, the stroke of the probe of the probe card can not ensure the effective contact between the probe and the wafer, and the effective contact between the probe and the wafer is the premise to ensure the yield and reliability of the wafer test. In the prior art, it is urgent to analyze and improve the accuracy and error sources of the probe testing system.

Based on the above, the present application provides a technical scheme to solve the above technical problems.

### SUMMARY OF THE INVENTION

The first object of the present invention is to provide a probe card stroke compensation system, which can ensure the wafer testing yield and reliability.

The second object of the present invention is to provide a probe card stroke compensation method, which can ensure the wafer test yield and reliability.

The third object of the present invention is to provide a wafer testing system, which can ensure the wafer testing yield and reliability.

The first aspect of the present invention is to provide a probe card stroke compensation system, which can be applied to a wafer test system, and the probe card in the wafer test system includes a probe head, comprising:

a measuring unit, which is used for measuring the stroke of a single probe and the flatness of all probes; and the total elastic force of the probe card is calculated according to the numerical values of the stroke and flatness:

a pressure sensor unit, the pressure sensor and the probe head can be replaced with each other, and the stroke compensation value of the probe card is obtained according to the relationship between the pressure and the stroke measured by the pressure sensor.

In a preferred embodiment of the present invention, in the wafer testing system, the probe head comprises a plurality of probes.

The plurality of probes are electrically connected with the carrier PCB, and the carrier PCB controls the probes.

The plurality of probes are also connected with a structural member, and the structural member is provided with the probe head, the measuring unit and the pressure sensor unit.

In a preferred embodiment of the invention, the structural dimension of the pressure sensor unit is consistent with that of the probe head.

The second aspect of the present invention provides a probe card stroke compensation method:
measuring the stroke of a single probe and the flatness of all probes; and calculating the total elastic force of the probe card according to the numerical values of the stroke and flatness;
the pressure sensor and the probe head with the same size are replaced with each other, and the stroke compensation value of the probe card is obtained according to the relationship between pressure and stroke measured by the pressure sensor.

In a preferred embodiment of the invention, when testing the stroke of a single probe, the stroke is defined as the stroke of the pad of the wafer contacting the probe.

When measuring the flatness of all probes, all probes are numbered as 1, 2, 3 . . . X according to the length, and the shortest probe is numbered as probe No. X.

The measured flatness values of all the probes are a1, a2 . . . ax.

When calculating the total elastic force of the probe card, Fₜₒₜₐₗ=f(OD)+f (OD-a2)+f(OD-a3)+ . . . +f(OD-ax).

The Fₜₒₜₐₗ is the total elastic force.

The f(OD) is the elastic force of the first probe.

The f(OD-a2) is the elastic force of the second probe, and the elastic force of the second probe is a dependent variable of the OD and the flatness of the second probe.

The f(OD-a3) is the elastic force of the third probe, and the elastic force of the third probe is a dependent variable of the OD and the flatness of the probe.

The f(OD-ax) is the elastic force of the No. X probe, and the elastic force of the No. X probe is a dependent variable of the OD and the flatness of the No. X probe.

In a preferred embodiment of the invention, when the relationship between pressure and stroke is measured according to the pressure sensor, the stroke of probe station's stroke is defined as POD.

Define the actual travel of the probe card as AOD.

Define the total strain of the structure as DEF, then POD=AOD+DEF.

In a preferred embodiment of the present invention, in order to obtain the required AOD, the POD or DEF is adjusted accordingly.

The third aspect of the present invention also provides a wafer testing system, which comprises the probe card stroke compensation system according to the present invention.

The invention can bring at least one of the following beneficial effects:

This scheme can be used to compensate the probe stroke of probe card in wafer test, and ensure the effective contact between probe and wafer, thus ensuring the yield and reliability of wafer test.

### BRIEF DESCRIPTION OF THE DRAWINGS

In the following, the preferred embodiment will be explained in a clear and easy-to-understand way with reference to the drawings, and the above characteristics, technical features, advantages and implementation methods will be further explained.

FIG. 1 shows an existing probe, which has a certain shape recovery capability:

FIG. 2 shows a curve of the stroke and the probe elastic force of the prior art:

FIG. 3 shows a wafer testing system of the prior art:

FIG. 4 exemplarily shows the probe stroke OD in the wafer testing process of the present invention:

FIG. 5 shows the stroke and elastic force curve of a single probe in the wafer testing of FIG. 4:

FIG. 6 shows the total elastic force curve of five probes in the wafer test of FIG. 4:

FIG. 7 shows a curve of the pressure and strain of the pressure sensor module in the wafer test of FIG. 4:

FIG. 8 shows the wafer testing system used in the wafer testing process of FIG. 4, in which the pressure sensor and the probe head can be replaced with each other;

FIG. 9 shows a curve of the pressure and POD of the wafer test system of FIG. 8.

### DETAILED DESCRIPTION

Various aspects of the present invention are described in further detail below.

Unless otherwise defined or specified, all professional and scientific terms used herein have the same meanings as those familiar to those skilled in the art. In addition, any method and material similar to or equal to the recorded content can be applied to the method of the invention.

The terms are explained below.

In this field, OD, that is, “probe stroke”, means that the position where the probe just touches the wafer pad is recorded as zero point, and the probe will be deformed to generate greater elastic force if the pressure is continuously applied. Here, in the process of applying greater pressure, the normal deformation of the probe is the stroke. The English abbreviation of itinerary is OD (Over Drive or Over travel).

Unless otherwise specified and limited, the “or” in the present invention includes the relationship of “and”. The “and” is equivalent to Boolean logic operator “AND”, the “or” is equivalent to Boolean logic operator “OR”, and AND is a subset of OR.

It will be understood that although the terms “first”, “second” and the like may be used herein to describe different elements, these elements should not be limited by these terms. These terms are only used to distinguish one element from another. Therefore, the first element can be called the second element without departing from the teaching of the concept of the invention.

In the present invention, the terms “comprise”, “contain” or “include” mean that various ingredients can be applied together in the mixture or composition of the present invention. Therefore, the terms “consisting mainly of” and “consisting of” are included in the terms “comprise”, “contain” or “include”.

Unless otherwise specified and limited, the terms “link”, “connect” and “communicate” in the present invention should be broadly understood, for example, they can be fixed connection, connected through an intermediary, connected inside two elements or interactive relationship between two elements. For those skilled in the art, the specific meanings of the above terms in this application can be understood according to the specific circumstances.

For example, if an element (or component) is said to be on, coupled with or connected with another element, the element can be directly formed on, coupled with or connected with the other element, or there can be one or more intervening elements between them. On the contrary, if the expressions “directly on”, “directly coupled with” and “directly connected with” are used here, it means that there are no intervening elements. Other words used to describe the relationship between elements should be interpreted similarly, such as “between” and “directly between”, “attached” and “directly attached”, “adjacent” and “directly adjacent” and so on.

In addition, the words “front”, “back”, “left”, “right”, “upper” and “lower” used in the following description refer to the directions in the drawings. The terms “inside” and “outside” are used to refer to the direction towards or away from the geometric center of a specific part, respectively. It will be understood that these terms are used herein to describe the relationship of one element, layer or region with respect to another element, layer or region as shown in the drawings. These terms should also include other orientations of the device besides those depicted in the drawings.

Other aspects of the present invention will be apparent to those skilled in the art due to the disclosure herein.

In order to more clearly explain the embodiment of the present invention or the technical scheme in the prior art, the specific embodiment of the present invention will be described below with reference to the drawings. Obviously, the drawings in the following description are only some embodiments of the present invention. For those skilled in the art, other drawings and other embodiments can be obtained according to these drawings without creative work.

It should also be noted that the diagrams provided in the following examples only illustrate the basic concept of this application in a schematic way, and only the components related to this application are shown in the diagrams, instead of being drawn according to the number, shape and size of components in actual implementation. In actual implementation, the types, numbers and proportions of components can be changed at will, and the layout of components may be more complicated. For example, the thickness of elements in the drawings may be exaggerated for clarity.

### Embodiment

In the current probe test, the following are common scenarios that lead to new problems, and the corresponding solutions adopted to solve the new problems:

### Scenario 1: In Order to Determine OD, it is Necessary to Control the Lateral Mutual Contact Between Probe and Probe.

The probe used in the probe card is usually only a few tens of microns in size and only 4-7 mm in length, and the elastic force of the probe is basically about 5 g (the elastic force of the probe will be different in different applications).

Usually, not one probe but a group of probes work at the same time during the test. Usually, there may be thousands of probes in a group. The pitch of chip pads is generally below 100 μm, which means that thousands of probes need to be installed in a small area, and the pitch between them is also very small.

After the probe contacts with the wafer, a certain force is applied in the vertical direction of the probe, and at the same time, a displacement in the vertical direction is generated, which is called an overdrive, generally between 25 and 120 um. Appropriate OD can generate appropriate probe pressure, and one end of the probe can pierce the oxide layer of the chip pad to achieve the purpose of electrical contact.

When the probe is displaced in the vertical direction, it will also bend in the lateral direction. If the direction of lateral deformation of the probe is not controlled by some means or the shape and size of the probe are unreasonable, the lateral displacement caused by the probe will make the probe contact with each other to form a path.

Scenario 2: The Increase in the Number of Probes Makes the Technical Route Change from “Controlling Contact” to “Calculating Effective Contact”

With the improvement of wafer manufacturing capacity and high-density market demand, the number of probes in some applications has exceeded 20000 pin, so the thrust requirement of wafer carrier in the probe station in chip testing needs to reach 100 kg, which raises the structural strength and precision requirements of probe cards and probes to a new level. After the probe is stuck on the wafer pad, it needs to continue to apply pressure to make the probe deform and generate greater elastic force, thus ensuring the electrical contact between the probe and the pad and ensuring the normal transmission of electrical signals between the test machine and the wafer.

In the wafer test in the prior art, the stroke of the probe card can not ensure the effective contact between the probe and the wafer, and the effective contact between the probe and the wafer is the premise to ensure the yield and reliability of the wafer test. The existing technology urgently needs to analyze and improve the accuracy and error source of the probe testing system.

In the invention, the inventor has conducted extensive and in-depth tests to ensure the effective contact between the probe and the wafer, and the effective contact between the probe and the wafer is the premise of ensuring the wafer test yield and reliability.

Hereinafter, specific embodiments of the present invention will be illustrated with reference to the accompanying drawings.

In order to realize the effective stroke evaluation and compensation of the wafer testing system, the invention provides a new method for evaluating and compensating the system, which can ensure the validity and accuracy of the stroke to the greatest extent.

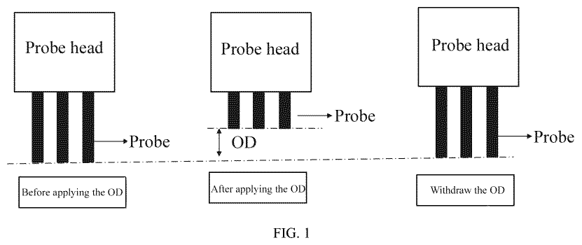

Referring to FIG. 1, the prior art probe has a certain shape recovery capability, so long as the maximum stroke of the probe is not exceeded, the probe can be recovered to the initial height, similar to the recovery of a spring.

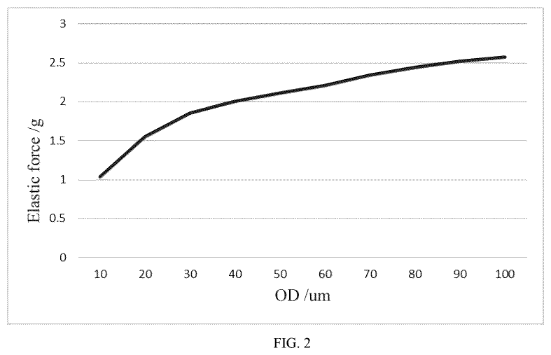

Referring to FIG. 2, the curve between the probe stroke and the probe elastic fore of the prior art is shown. The elastic force of the probe is very related to the stroke. If the stroke cannot be accurately controlled, the electrical contact between the probe and the wafer cannot be guaranteed.

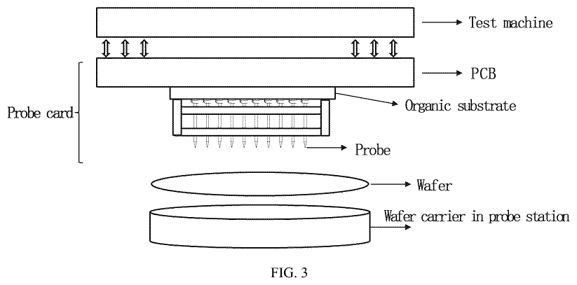

Referring to FIG. 3, a prior art wafer testing system is shown.

The main tools in the wafer testing system are as follows,
1. Test machine
2. Probe card
3. Probe station
4. Wafer

During wafer testing, the wafer in the following figure is adsorbed on the wafer carrier in the probe station, and the carrier moves up along the Z axis to complete the contact between the wafer and the probe card. At the same time, after completing a test, the carrier will move in the XY direction, and the chip to be tested next time will be moved below the probe card. During the test, the probe card and the above parts will not move, but will be deformed due to the force.

The structural strength and precision of wafer testing system will seriously affect the effective test stroke of probe card. It is a complicated problem to evaluate the effective test stroke of probe card. For example, when testing, the theoretical stroke (AOD) of the probe card needs to be designed to be 100 μm. If the mechanical deformation caused by the probe elasticity is 10 μm, then when the test program sets the test stroke (POD) to be 100 μm, the AOD is only 90 μm.

Therefore, a first aspect of the present invention provides a probe card stroke compensation system, which can be applied to a wafer testing system, and the probe card in the wafer testing system includes a probe head, including:

The measuring unit, which is used for measuring the stroke of a single probe and the flatness of all probes; and the total elastic force of the probe card is calculated according to the numerical values of the stroke and flatness:

A pressure sensor unit, wherein that pressure sensor and the probe head can be replaced with each other, and the stroke compensation value of the probe card is obtained according to the relationship between the pressure and the stroke measured by the pressure sensor.

In a preferred embodiment of the present invention, in the wafer testing system, the probe head comprises a plurality of probes.

The plurality of probes are electrically connected with the carrier PCB, and the carrier PCB controls the probes.

The plurality of probes are also connected with a structural member, and the structural member is provided with the probe head, the measuring unit and the pressure sensor unit.

In a preferred embodiment of the invention, the structural dimension of the pressure sensor unit is consistent with that of the probe head.

The operating principle of the probe card stroke compensation system is described in detail below.

The second aspect of the present invention provides a probe card stroke compensation method:

measuring the stroke of a single probe and the flatness of all probes; and and calculating the total elastic force of the probe card according to the numerical values of the stroke and flatness:

the pressure sensor and the probe head with the same size are replaced with each other, and the stroke compensation value of the probe card is obtained according to the relationship between pressure and stroke measured by the pressure sensor.

In a preferred embodiment of the invention, when measuring the stroke of a single probe, the stroke is defined as the stroke of the pad of the wafer contacting the probe.

When measuring the flatness of all probes, all probes are numbered as 1, 2, 3 . . . X according to the length, and the shortest probe is numbered as probe No. X.

The measured flatness values of all the probes are a1, a2 . . . ax.

When calculating the total elastic force of the probe card, Fₜₒₜₐₗ=f(OD)+f (OD-a2)+f(OD-a3)+ . . . +f(OD-ax).

The Fₜₒₜₐₗ is the total elastic force.

The f(OD) is the elastic force of the first probe.

The f(OD-a2) is the elastic force of the second probe, and the elastic force of the second probe is a dependent variable of the OD and the flatness of the second probe.

The f(OD-a3) is the elastic force of the third probe, and the elastic force of the third probe is a dependent variable of the OD and the flatness of the probe.

The f(OD-ax) is the elastic force of the No. X probe, and the elastic force of the No. X probe is a dependent variable of the OD and the flatness of the No. X probe.

In a preferred embodiment of the invention, when the relationship between pressure and stroke is measured according to the pressure sensor, the stroke of probe station is defined as POD.

Define the actual travel of the probe card as AOD.

Define the total strain of the structure as DEF, then POD=AOD+DEF.

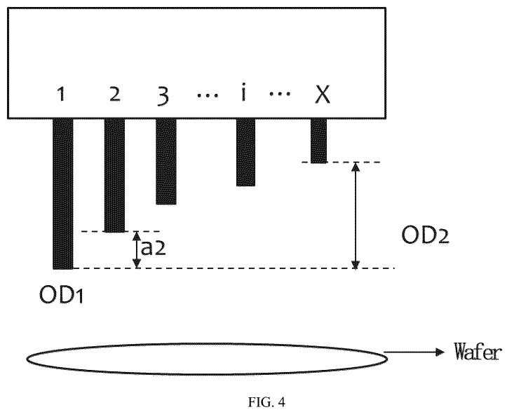

Refer to FIG. 4-FIG. 9 for details. Here, a case will be used to illustrate the specific implementation steps of this method, so as to explain the related dimension relationship of the probe card, which is represented by characters here.

With specific reference to FIG. 4, the probe head part of the probe card is shown. The number of probes in the probe card is No. X, and each probe is numbered, and the probe numbers are 1, 2, 3 . . . X. Wherein, the probes are numbered according to the length, the longest probe is numbered as the No. 1 probe, the shortest probe is numbered as the No. X probe, and others are analogized according to the length. During wafer testing, the probe stroke is expressed by OD, that is, the rising distance of the wafer (generally, the position where the wafer just touches the probe is 0 point), which only defines two strokes, OD1 is the stroke when the wafer pad contacts the No. 1 probe, and OD1-0) can be defined here for the convenience of calculation, and OD2 is the stroke when the wafer pad contacts the No. X probe. Meanwhile, the height difference between probe No. 2 and probe No. 1 is defined as a2, and the height difference between probe No. i and probe No. 1 is defined as ai. It can be concluded that OD2=OD1+ax. In addition, the stroke set by the program of the wafer carrier in the probe station is defined as POD, where OD1 is the zero point of POD. The actual stroke of the probe card is AOD, which is affected by structural stability and other factors, because all structural parts will be deformed after being stressed. If the total strain of the structure is DEF, POD=AOD+DEF.

Referring to FIG. 5, the first step is to test the stroke and elastic force curve of a single probe.

Step 2, measure the flatness of all probes of the probe card, that is, the probe height difference, and get a1, a2 . . . ax.

Step 3, calculate the total elastic curve of the probe card AOD from 10 μm to 100 μm. The interval of AOD can be 2 μm, and when the AOD is 100 μm, the total elastic force of the probe is the largest, which is denoted as Fmax. Here, it is necessary to calculate the flatness, and the OD of different probes will be different. For example, when the OD of probe No. 1 is 50 μm, the OD of probe No. 2 is (50−a2)μm, and so on, and the OD of probe No. X is (50−ax)μm: When the OD of probe No. 1 is 100 μm, the OD of probe No. 2 is (100-a2)μm, and so on, the OD of probe No. X is (100-ax)μm.

If the elastic force of a single probe is F=f(OD), then Ftotal=f(OD)+f (OD-a2)+f(OD-a3)+ . . . +f(OD-ax), and draw the total elastic force curve according to this formula.

Taking 5 probes as an example, if a2=10 μm, a3=20 μm, a4=30 μm and a5-40 μm, the following table 1 can be obtained by calculation.

TABLE 1
Calculation of Elastic Force of 5 Probes

| | Elastic Force | | | | | |
|---|---|---|---|---|---|---|
| | | | | | | Total |
| Probe | | | | | | Elastic |
| OD | | | | | | Force |
| (um) | No. 1 | No. 2 | No. 3 | No. 4 | No. 5 | (g) |
| 10 | 2.08 | 0 | 0 | 0 | 0 | 2.08 |
| 20 | 3.1 | 2.08 | 0 | 0 | 0 | 5.18 |
| 30 | 3.7 | 3.1 | 2.08 | 0 | 0 | 8.88 |
| 40 | 4 | 3.7 | 3.1 | 2.08 | 0 | 12.88 |
| 50 | 4.22 | 4 | 3.7 | 3.1 | 2.08 | 17.1 |
| 60 | 4.42 | 4.22 | 4 | 3.7 | 3.1 | 19.44 |
| 70 | 4.68 | 4.42 | 4.22 | 4 | 3.7 | 21.02 |
| 80 | 4.88 | 4.68 | 4.42 | 4.22 | 4 | 22.2 |
| 90 | 5.04 | 4.88 | 4.68 | 4.42 | 4.22 | 23.24 |
| 100 | 5.14 | 5.04 | 4.88 | 4.68 | 4.42 | 24.16 |

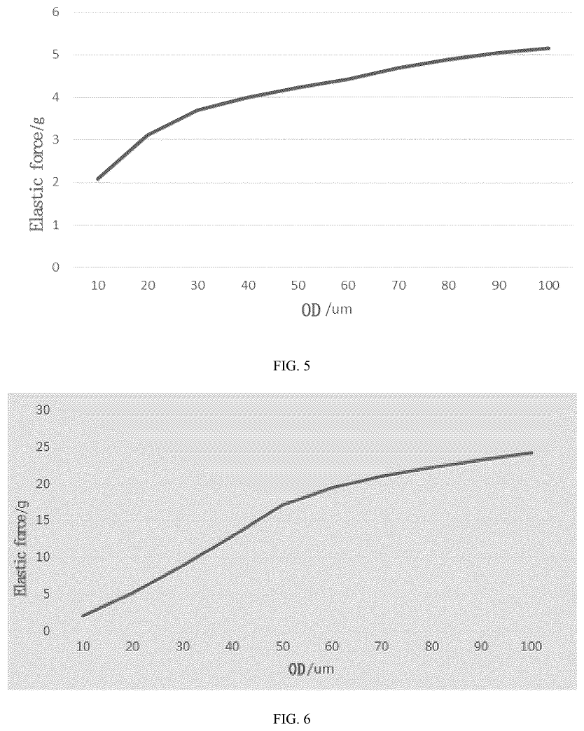

Referring to FIG. 6, the total elastic force curve of five probes is shown.

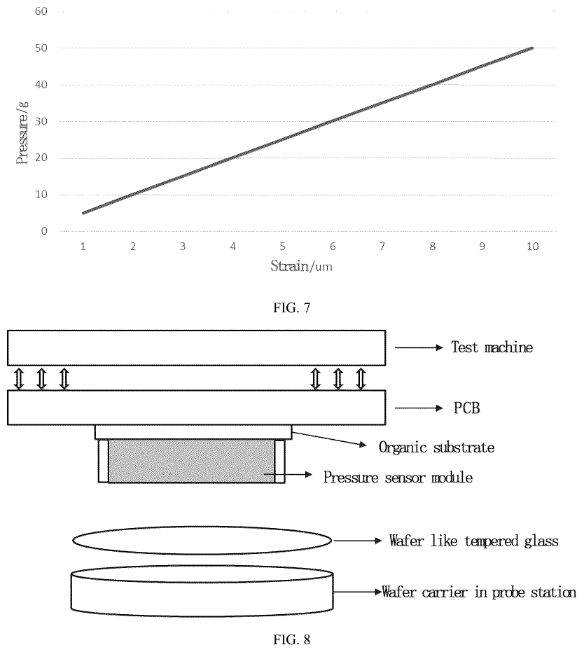

Step 4, make a pressure sensor module with the same structural size as the probe head, which can detect the pressure. And the curve of pressure and strain of the pressure sensor module is tested (see FIG. 7). Read the strain DEF1 corresponding to Fmax from the curve, which is shown in the following figure (to match the scene of the above 5 probes, the pressure is small, and here is only to illustrate the principle). Considering that the total probe Fmax of the above 5 probes is close to 25 g, it can be seen from the following figure that the pressure of the module is 25 g when the strain is 5 μm.

Step 5, Assemble the pressure sensor module on the wafer testing system (see FIG. 8). Except for replacing the probe with the pressure sensor module, other parts remain the same (the wafer is replaced with tempered glass), especially the structural parts of the test machine and the pin card which have great influence.

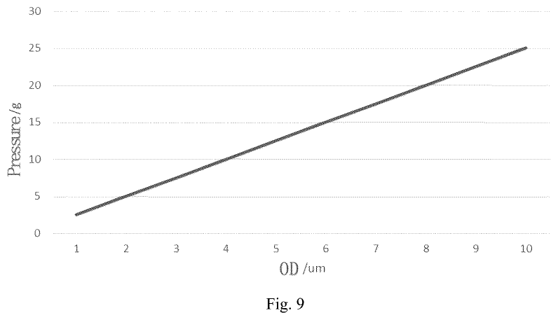

Step 6, use the system assembled in step 5 to gradually increase the POD, and the increase range should be as small as possible, with 1 um as appropriate. In the process of increasing POD, the reading of pressure sensor will gradually increase, and the curve between pressure and POD will be recorded (see FIG. 9). When the pressure is close to or equal to Fmax, it will stop. Take the strain DEF2 at Fmax, and DEF=DEF2−DEF1. Combined with the scene of the above 5 probes, for example, when the POD is 10 μm, the pressure is 25 g. Therefore, DEF=10 um=5 um=5 um.

Step 7, according to the above analysis, DEF=5 μm, if you want to ensure AOD=100 um. POD must be set to 105 um. In fact, due to the large number of project probes, the calculation is far more complicated than this simple example, but there is no difference in the calculation method.

FIG. 8 shows the wafer testing system used in the wafer testing process of FIG. 4, in which the pressure sensor and the probe head can be replaced with each other;

FIG. 9 shows a curve of the pressure and POD of the wafer test system of FIG. 8.

To sum up, the specific embodiment of the present invention proves that the following effects can be obtained:

This method can accurately and effectively compensate the stroke of the probe card and eliminate the strain caused by the system structure, so as to ensure that the probe of the probe card is kept in a very good state during the test, to reduce the damage to the probe card during the test, to save the cost, to improve the working efficiency and to ensure the test yield.

Based on the present application, it should be understood by those skilled in the art that one aspect described herein can be implemented independently of any other aspect, and two or both of these aspects can be combined in various ways. For example, any number and aspects set forth herein may be used to implement the apparatus and/or the recipe. In addition, the apparatus and/or the method may be implemented using other structures and/or functionality besides one or more of the aspects set forth herein.

Those skilled in the art know that in addition to implementing the system and its various devices, modules, and units provided by the present invention in pure computer-readable program code, it is entirely possible to program the method steps logically to enable the system and its various devices, modules, and units provided by the present invention to achieve the same function in the way of logic gates, switches, specialized integrated circuits, programmable logic controllers and embedded micro-controllers. Therefore, the system and its various devices, modules, and units provided by the present invention can be considered as hardware components, and the devices, modules, and units included therein for achieving various functions can also be considered as structures within hardware components; Devices, modules, and units used to implement various functions can also be considered as software modules that can implement methods or as structures within hardware components.

It should be noted that all the above embodiments can be freely combined as required. The above is only the preferred embodiment of the present invention, and it should be pointed out that a person skilled in the art can make several improvements and embellishments without departing from the principle of the present invention, and these improvements and embellishments should also be regarded as the protection scope of the present invention.

All documents mentioned in the present invention are incorporated by reference in this application as if each document were individually incorporated by reference. Furthermore, it should be understood that after reading the above contents of the invention, those skilled in the art can make various changes or modifications to the invention, and these equivalent forms also fall within the scope defined by the appended claims of this application.

The invention claimed is:

1. A probe card stroke compensation system, which can be applied to a wafer testing system, wherein a probe card in the wafer testing system comprises a probe head, comprising:
a measuring unit, which is used for measuring a stroke of a single probe and flatness of all probes; and wherein total elastic force of the probe head is calculated according to numerical values of the stroke and flatness;
a pressure sensor unit, wherein a pressure sensor and a probe head can be replaced with each other, and wherein a stroke compensation value of the probe card is obtained according to relationship between the pressure and the stroke measured by the pressure sensor before and after the replacement;
wherein:
when measuring the stroke OD of a single probe, the stroke is defined as the stroke when the pad of the wafer contacts the probe;
when measuring the flatness of all probes, all probes are numbered as 1, 2, 3 . . . X according to the length, and the shortest probe is numbered as probe No. X;
the measured flatness values of all the probes are a1, a2 . . . ax;
when calculating the total elastic force of the probe card, Fₜₒₜₐₗ=f(OD)+f(OD-a2)+f(OD−a3)+ . . . +f(OD-ax);
the Fₜₒₜₐₗ is the total elastic force;
and the f(OD) is the elastic force of the first probe;
the f(OD-a2) is the elastic force of the second probe, and the elastic force of the second probe is a dependent variable of the OD and the flatness of the second probe;
the f(OD-a3) is the elastic force of the third probe, and the elastic force of the third probe is a dependent variable of the OD and the flatness of the probe;
the f(OD-ax) is the elastic force of the No. X probe, and the elastic force of the No. X probe is a dependent variable of the OD and the flatness of the No. X probe.

2. The probe card stroke compensation system according to claim 1 wherein:
in the wafer testing system, the probe head comprises a plurality of probes;
the plurality of probes are electrically connected with a carrier PCB, and the carrier PCB controls the probes;
the plurality of probes are also connected with a structural member, and the structural member is provided with the probe head, the measuring unit and the pressure sensor unit.

3. The probe card stroke compensation system according to claim 1 wherein:
the structural dimension of the pressure sensor unit is consistent with that of the probe head.

4. A probe card stroke compensation method, comprising the following steps:
measuring a stroke of a single probe and a flatness of all probes; and calculating total elastic force of the probe head according to the numerical values of the stroke and flatness;
replacing the pressure sensor and the probe head with the same size with each other, and the stroke compensation value of the probe card is obtained according to the relationship between pressure and stroke measured by the pressure sensor before and after replacement;
wherein:
when measuring the stroke OD of a single probe, the stroke is defined as the stroke when the pad of the wafer contacts the probe;
when measuring the flatness of all probes, all probes are numbered as 1, 2, 3 . . . X according to the length, and the shortest probe is numbered as probe No. X;
the measured flatness values of all the probes are a1, a2 . . . ax;
when calculating the total elastic force of the probe card, Ftotal=f(OD)+f(OD-a2)+f(OD-a3)+ . . . +f(OD-ax);
the Ftotal is the total elastic force;
And the f(OD) is the elastic force of the first probe;
the f(OD-a2) is the elastic force of the second probe, and the elastic force of the second probe is a dependent variable of the OD and the flatness of the second probe;
the f(OD-a3) is the elastic force of the third probe, and the elastic force of the third probe is a dependent variable of the OD and the flatness of the probe;
the f(OD-ax) is the elastic force of the No. X probe, and the elastic force of the No. X probe is a dependent variable of the OD and the flatness of the No. X probe.

5. (canceled)

6. The probe card stroke compensation method according to claim 4 wherein:
when the relationship between pressure and stroke is measured according to the pressure sensor,
define probe station's stroke as POD;
define the actual stroke of the probe card as AOD;
define the total strain of the structure as DEF, then POD=AOD+DEF.

7. The probe card stroke compensation method according to claim 5 wherein: the POD is adjusted accordingly in order to obtain the required AOD.

8. A wafer testing system, comprising the probe card stroke compensation system according to claim 1.
